(19) United States
(12) Patent Application Publication
(10) Pub. No.: US 2009/0292504 A1
(43) Pub. Date: Nov. 26, 2009

(54) Adaptive Image Sensor

(76) Inventor: Alfred M. Haas, Hyattsville, MD (US)

Correspondence Address: Alfred M. Haas, 3410 Tulane Drive, Apt. 31, Hyattsville, MD, 20783, US

(21) Appl. No.: 12/422,980

(22) Filed: Apr. 13, 2009

Related U.S. Application Data
(60) Provisional application No. 61/044,280, filed on Apr. 11, 2008.

(51) Int. Cl. G06F 17/18; H01L 27/00

(52) U.S. Cl. 702/179; 250/208.1

(57) ABSTRACT

This invention pertains to an image sensor that detects when the light intensity incident on the sensor rises significantly above and/or drops significantly below the ambient, background, or user-set light intensity.

### CROSS-REFERENCE TO RELATED APPLICATIONS

Pursuant to 35 USC § 119(e) and as set forth in the Application Data Sheet, this utility application claims the benefit of priority from U.S. Provisional Patent Application No. U.S. 61/044,280 (“the '280 provisional”), which is incorporated herein in its entirety by reference.

### STATEMENT REGARDING FEDERALLY SPONSORED RESEARCH OR DEVELOPMENT

Not applicable.

### REFERENCE TO SEQUENCE LISTING, A TABLE, OR A COMPUTER PROGRAM LISTING COMPACT DISC APPENDIX

Not Applicable.

### BACKGROUND OF THE INVENTION

This invention claims priority from the '280 provisional, and the disclosures contained therein.

There are many means of transducing light into electrical signals. Among the most common found in imaging arrays are charge-coupled-devices and active pixel sensors, or “APS”. Conventional APS imagers produce images by directly measuring the current or voltages generated by incident light falling on the photodiodes that comprise the imager. One drawback of such imagers, however, is that the conventional imager “sees” as a camera would, without attributing any particular significance to the patterns of light and dark that it conveys. Thus, a classical APS imager cannot discriminate edges, locate a region of interest, or detect specific features. It merely provides a mapping of light and dark, and any additional information that must be gleaned from the image is relegated to off-array or off-chip post-processing. While this mode of operation may be satisfactory for many applications, it is undesirable for highly integrated systems. In particular, for imagers tailored e.g. to the detection and in-situ control of microparticles, or for sensors seeking to monitor sparse neural activity, additional image processing circuitry is desired.

On-chip image-plane processing may be performed in many different ways. However, for applications requiring the detection of objects or events, it is wasteful to expend resources imaging the entire image frame. It would instead be desirable to have an imager identify the specific regions that correspond with the locations of objects or events being sensed in real-time. As disclosed in the '280 provisional, a hybrid image-plane processor was fabricated to identify the dark regions of the image frame occluded by cells or microparticles without the necessity of reading out every APS in the image frame.

However, in characterizing this hybrid image-plane processor, it was found that the inability of the image sensor to adapt to changes in ambient light intensity caused difficulties in the reliable detection of optical events. More specifically, when ambient light intensity changed, the user had to adjust the threshold or incur potentially false positive detections or false negative quiescence. In order to overcome this problem, it was desired to create a sensor that could automatically set an adaptive threshold to distinguish meaningful optical events from background or ambient illumination conditions.

In searching for a way to establish a meaningful threshold, it was observed that statistical variance defines the normal distributions that are typically used to characterize many physical processes and events such as device mismatch, circuit noise, and the spatial distribution of illumination intensity from certain light sources. Likewise, the standard deviation about a mean defines the statistical significance of an event. It is well known to those of skill in the art how to perform variance, standard deviation and other similar computations by hand, or using sophisticated computer software. However, in order to ascertain whether certain optical activity, such as detected optical spikes from an active voltage-dyed or synaptopHluorin producing neuron, is statistically meaningful and therefore worth registering in real-time, it is highly desirable to have a means of evaluating the statistical parameters, such as mean, variance and standard deviation, of the background or ambient illumination intensity in hardware. It is further desirable that such means of computing these statistical parameters, such as mean, variance and standard deviation be compact, be able to be integrated with other circuitry on-chip, and also that they also be power efficient. In addition, it is desirable to be able to use such circuitry to automatically and independently set a threshold for optical event detection.

The text by J. Baker, “CMOS Circuit Design, Layout and Simulation,” 2d Edition, Copyright 2005, Institute for Electrical and Electronics Engineers, Inc. (“IEEE”), and published by the IEEE and Wiley-Interscience (“the Baker text”) discloses fundamentals of integrated CMOS circuit design at the level of an undergraduate university course. In addition, the text “Floating Gate Devices: Operation and Compact Modeling” by P. Pavan, L. Larcher, and A. Marmiroli, Copyright 2004, Kluwer Academic Publishers, Inc., (“the FG text”) discloses information about the physics and general operation of floating gate devices.

The discussion of the background of the invention herein is included to explain the context of the invention. Although each of the patents and publications cited herein are hereby incorporated by reference, neither the discussion of the background nor the incorporation by reference is to be taken as an admission that any of the material referred to was published, known, or part of the common general knowledge as at the priority date of any of the claims.

### BRIEF SUMMARY OF THE INVENTION

This invention comprises an image sensor that detects when the light intensity incident on the sensor rises significantly above and/or drops significantly below the ambient, background, or user-set light intensity. In one embodiment, the image sensor generates a digital output when the light intensity incident on the sensor crosses a threshold.

### BRIEF DESCRIPTION OF THE SEVERAL VIEWS OF THE DRAWING

FIG. 1 is a schematic of an active pixel sensor of one embodiment of the present invention.

FIG. 2 illustrates the principle of adaptive thresholding with respect to a normal distribution using the mean and standard deviation.

FIG. 3 shows the computed standard deviation from measured variance estimation circuit data, demonstrating the theoretical performance of a component of one embodiment of the present invention.

### DETAILED DESCRIPTION OF THE INVENTION

The invention comprises an image sensor that detects when the light intensity incident on the sensor rises significantly above and/or drops significantly below the ambient, background, or user-set light intensity.

In one fabricated embodiment of the present invention, an APS imager has adaptive in-pixel thresholding that is triggered when incident light levels rise significantly above or fall significantly below the background light intensity. In this embodiment, the adaptive threshold is set by on-chip ultra-low-power current-mode CMOS circuits which continuously compute the mean and standard deviation of the photocurrents generated by a number of representative pixels. Sensor pixels of this embodiment discriminate between light and dark by integrating onto the APS photodiode junction capacitance the difference between the photo current and an opposing bias current whose magnitude may be automatically set by tunable mean and standard deviation circuits in real-time. Optical (occlusion) events will discharge (charge) the photodiode, resulting in threshold crossings that can be encoded and queued for serial address event representation (“AER”) readout. As a result, the sensor can more intelligently discriminate between light (e.g., optical spikes from active voltage-dyed or synaptopHluorin producing neurons), and dark (e.g., biological cell or particle occludes the pixel) events.

In other disclosed embodiments of the invention, the image sensor may be a photodiode, an active pixel sensor, a charge-coupled-device, or any other sensor that transduces incident light into electrical current or voltage. A positive and negative trigger may be included in the same sensor, or implemented separately according to other embodiments of the invention. In addition, there need not be a fixed number of sensors/pixels which are sampled to estimate the background light intensity—as few as one (in this case a temporal rather than a spatial standard deviation and mean would be computed), and as many as can be integrated into a given process for a particular application may be sampled.

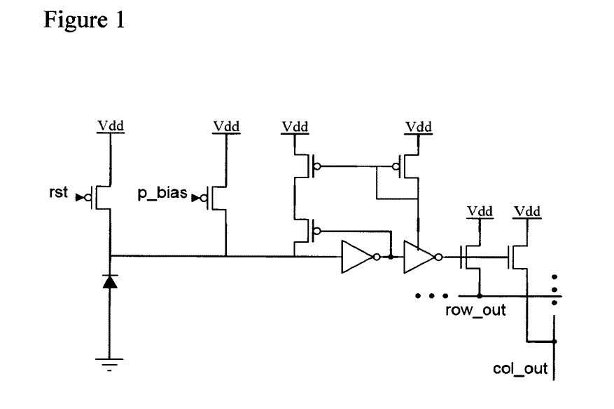

Other means for thresholding in addition to the simple inverters shown in the schematic of FIG. 1, such as in-pixel comparators that employ a voltage or current threshold and competitive inhibition mechanisms such as those found in biological systems to detect optical events are also expressly included within the scope of this invention. In addition, background pixels used to compute local or ambient statistical illumination intensity parameters, such as mean, variance and standard deviation, may be sampled continuously or in discrete-time. Likewise, the adaptively tuned threshold value (e.g., bias current or voltage, comparator threshold, or inhibition level) may be continuously tuned, or periodically updated. Furthermore, the circuits that comprise the present invention may be clocked or asynchronous.

In similar fashion, it is possible to adapt and/or set the threshold or comparison or inhibition value based on the mean and standard deviation, as described above, and also to set these values based on other statistical parameters such as the variance, correlation, cross-correlation, and mean square of sensor photo currents—each of these computations may be performed by methods and circuits disclosed herein by a person of ordinary skill in the art.

In one embodiment, the standard deviation is computed as the square root of the sample variance, defined mathematically as σ²=E[(X−E[X])²]=E[X²]−E²[X], where

$$E [ X ] = \frac{1}{N} {\sum }_{k = 1}^{N} {x}_{k}$$

is the expected value, or mean, of a random variable, X, corresponding with the sampled input signals. In a fabricated physical implementation of this embodiment, the circuit computes σ² (I) by: (a) copying N input currents, i(0) . . . i(N); (b) individually squaring and then averaging one set of currents to generate E[I²]; (c) averaging and then squaring the average of the second set of currents, to compute E² [I]; and then (d) subtracting the second result from the first. The standard deviation is computed from the variance, σ²(I), by a square rooting circuit. The corresponding circuits of this embodiment are disclosed in the '280 provisional, which has been incorporated by reference.

In addition to the embodiments expressly described above, there are many other algorithms and hardware which may be used to detect optical or occlusion events which rise significantly above or fall significantly below the background light intensity, and which are intended to fall within the scope of the instant invention. In particular, in addition to the explicitly disclosed embodiments, the algorithms for setting an adaptive threshold of the present invention may also be implemented in BiCMOS, digital or mixed-signal circuits, on a micro controller, on a programmable integrated circuit (“PIC”), in FPGA's and/or in other hardware known to those of skill in the art. Likewise, the circuits for computing the mean and standard deviation may operate on electrical currents, charges, or voltages, or some combination of the three and, for CMOS realizations, may be designed to operate above-threshold, below-threshold or in any other operating regime.

In addition, the standard deviation may be computed stochastically, in a manner like that demonstrated in the paper by Reid R. Harrison, entitled “A Low-Power Integrated Circuit for Adaptive Detection of Action Potentials in Noisy Signals,” Proceedings of the 25th Annual International Conference of the IEEE EMBS, Cancun, Mexico, Sep. 17-21, 2003, pp. 3325-28, which shows a method of approximating the standard deviation of the noise in a signal, but which may be extended to any normally distributed input.

Finally, the sensor may be used for a variety of purposes, including, but not limited to, particle detection for handheld flow cytometry, neural action potential detection or optical spike detection generally, and in an array of sensors for contact imaging.

Although it is not believed that drawings are necessary for the understanding of the subject matter sought to be patented, for illustrative purposes we have included a figure related to a specific embodiment of the disclosed invention. FIG. 1 is a schematic of an active pixel sensor of one embodiment of the disclosed invention.

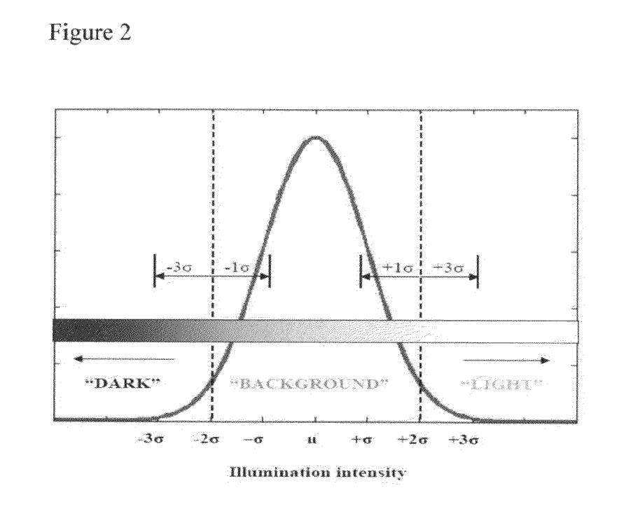

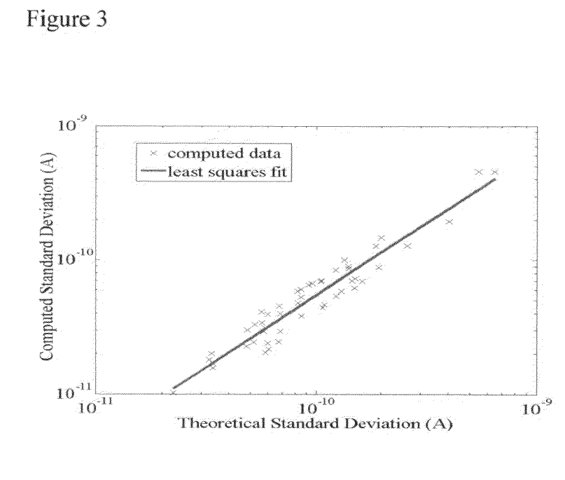

In addition, FIG. 2 illustrates the principle of adaptive thresholding with respect to a normal distribution using the mean and standard deviation. FIG. 3 shows the computed standard deviation from measured variance estimation circuit data, demonstrating the theoretical performance of a component of one embodiment of the present invention.

Although the foregoing invention has been described in some detail by way of illustration and example for purposes of clarity and understanding, it will be readily apparent to those of ordinary skill in the art in light of the teachings of this invention that certain changes and modifications may be made thereto without departing from the spirit and purview of this application or scope of the appended claims. All publications, patents, and patent applications cited herein are hereby incorporated by reference in their entirety.

I claim:

1. An adaptive image sensor that detects when the light intensity incident on the sensor crosses a threshold;

2. The adaptive image sensor of claim 1, wherein the image sensor generates and asserts one or more digital output signals when the light intensity incident on the sensor crosses a threshold;

3. The adaptive image sensor of claim 1, wherein the image sensor comprises an active pixel sensor.

4. The adaptive image sensor of claim 1, wherein the threshold is set by circuits which compute statistical parameters of the distribution of incident illumination intensity falling on one or more image sensors;

5. The adaptive image sensor of claim 4, wherein the statistical parameters comprise one or more of the mean, the variance, and the standard deviation of the incident illumination intensity;

6. The adaptive image sensor of claim 5, wherein the threshold is set proportional to the computed illumination intensity at some number of standard deviations away from the mean;

7. The adaptive image sensor of claim 4, wherein the image sensor transduces the incident illumination intensity to an electrical current and the circuits that compute the statistical parameters generate an opposing bias current;

8. The adaptive image sensor of claim 4, wherein the image sensor transduces the incident illumination intensity to an electrical voltage and the circuits that compute the statistical parameters set a voltage threshold;

9. The adaptive image sensor of claim 1, wherein the image sensor comprises one or more charge-coupled-devices;

10. A method of detecting optical events comprising ascertaining statistical parameters of the distribution of light intensity incident on one or more image sensors and setting a detection threshold based on the ascertained statistical parameters;

11. The method of claim 10, wherein the statistical parameters are measured directly;

12. The method of claim 10, wherein the statistical parameters are computed from measured data;

13. The method of claim 10, wherein the statistical parameters comprise one or more of the mean, the variance and the standard deviation of the incident illumination intensity;

14. The method of claim 10, wherein the statistical parameters are computed in real-time;

15. The method of claim 10, wherein the distribution of incident illumination intensity is a spatial distribution across a plurality of image sensors;

16. The method of claim 10, wherein the distribution of incident illumination intensity is a temporal distribution;

17. A plurality of image sensors one or more of which detects when the light intensity incident crosses a threshold, wherein the threshold is computed using circuits that calculate statistical parameters of the incident illumination intensity on one or more of the image sensors;

18. The method of claim 17, wherein the circuits calculate the statistical parameters in real-time;

19. The image sensors of claim 17, wherein the image sensors comprise an integrated circuit;

20. The image sensors of claim 19, wherein the image sensors comprise an array and wherein the circuits compute the mean and standard deviation of a representative number of elements of the array and automatically set a detection threshold proportional to some arithmetic combination of the computed mean and standard deviation of the incident illumination intensity.
